(19) United States
(12) Patent Application Publication
(10) Pub. No.: US 2024/0063076 A1
(43) Pub. Date: Feb. 22, 2024

(54) INTEGRATED CONFORMAL THERMAL HEAT SPREADER FOR MULTICHIP COMPOSITE DEVICES

(71) Applicant: Intel Corporation, Santa Clara, CA (US)

(72) Inventors: Mohammad Enamul Kabir, Portland, OR (US); Bhaskar Jyoti Krishnatreya, Hillsboro, OR (US); Kimin Jun, Portland, OR (US); Adel Elsherbini, Chandler, AZ (US); Tushar Talukdar, Wilsonville, OR (US); Feras Eid, Chandler, AZ (US); Debendra Mallik, Chandler, AZ (US); Krishna Vasanth Valavala, Chandler, AZ (US); Xavier Brun, Hillsboro, OR (US)

(73) Assignee: Intel Corporation, Santa Clara, CA (US)

(21) Appl. No.: 17/891,727

(22) Filed: Aug. 19, 2022

(51) Int. Cl. H01L 23/367; H01L 23/00; H01L 23/373; H01L 23/48; H01L 25/065

(52) U.S. Cl. CPC H01L 23/367; H01L 24/08; H01L 23/3736; H01L 23/373; H01L 23/3732; H01L 23/481; H01L 24/32; H01L 24/29; H01L 25/0657; H01L 2224/08145; H01L 2224/32225; H01L 2224/29147; H01L 2224/29124; H01L 2224/29139; H01L 2224/29144; H01L 2224/29193; H01L 2224/29186

(57) ABSTRACT

Microelectronic devices, assemblies, and systems include a multichip composite device having one or more integrated circuit dies bonded to a base die, a conformal thermal heat spreading layer on the top and sidewalls of the integrated circuit dies, and an inorganic dielectric material on a portion of the conformal thermal heat spreading layer, laterally adjacent the integrated circuit dies, and over the base die. The conformal thermal heat spreading layer includes a high thermal conductivity material to provide a thermal pathway for the integrated circuit dies during operation.

### BACKGROUND

As computing devices continue to get smaller and more powerful, thermal management presents new challenges. In particular, thermal management of multichip composite devices including a number of 3D stacked dies in a composite structure faces a number of challenges. Such multichip composite devices advantageously use thin top dies. However, deployment of the thin top dies make heat transfer difficult. In some contexts, difficulty in heat removal can have negative impacts such as damage to the device or the need to throttle the devices (i.e., reducing power), which negatively impacts performance. Therefore, there is a need to more efficiently remove heat from multichip composite devices.

It is with respect to these and other considerations that the present improvements have been needed. Such improvements may become critical as the desire to improve computing device performance and the corresponding necessity to remove heat from such devices becomes even more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A illustrates a cross-sectional side view of a multichip composite device including a conformal heat spreading layer to provide a thermal pathway for heat removal from top IC dies;

FIG. 1B illustrates an expanded cross-sectional plan view of a cross-section of the multichip composite device in FIG. 1A;

FIG. 2 illustrates a cross-sectional side view of a multichip composite device including a conformal heat spreading layer having a portion in contact with a base layer level through dielectric via;

FIG. 3 illustrates a cross-sectional side view of a multichip composite device including an intervening metal layer between a conformal heat spreading layer and a handle die;

FIG. 4 illustrates a cross-sectional side view of a multichip composite device including a selective intervening metal and dielectric layers between handle die and a conformal heat spreading layer and an inorganic dielectric material;

FIG. 5 is a flow diagram illustrating an example process for forming a multichip composite device including a conformal heat spreading layer to provide a thermal pathway for heat removal from IC dies of the multichip composite device;

FIGS. 6A, 6B, 6C, 6D, 6E, 6F, 6G, and 6H illustrate cross-sectional side views of multichip composite device structures as the operations of the process of FIG. 5 are performed;

FIG. 7 illustrates a cross-sectional side view of a multichip composite device including a conformal heat spreading layer over a multilevel IC die stack 701 to provide a thermal pathway for heat removal from top IC dies;

FIG. 8 illustrates an example microelectronic device assembly including a conformal heat spreading layer over IC dies of a multichip composite device for improved thermal conductivity pathways;

FIG. 9 illustrates exemplary systems employing an IC assembly including a conformal heat spreading layer over IC dies of a multichip composite device; and

FIG. 10 is a functional block diagram of an electronic computing device, all in accordance with some embodiments.

### DETAILED DESCRIPTION

One or more embodiments are described with reference to the enclosed figures. While specific configurations and arrangements are depicted and discussed in detail, it should be understood that this is done for illustrative purposes only. Persons skilled in the relevant art will recognize that other configurations and arrangements are possible without departing from the spirit and scope of the description. It will be apparent to those skilled in the relevant art that techniques and/or arrangements described herein may be employed in a variety of other systems and applications other than what is described in detail herein.

Reference is made in the following detailed description to the accompanying drawings, which form a part hereof and illustrate exemplary embodiments. Further, it is to be understood that other embodiments may be utilized and structural and/or logical changes may be made without departing from the scope of claimed subject matter. It should also be noted that directions and references, for example, up, down, top, bottom, and so on, may be used merely to facilitate the description of features in the drawings. Therefore, the following detailed description is not to be taken in a limiting sense and the scope of claimed subject matter is defined solely by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure. As used herein, the term predominantly indicates the predominant constituent (i.e., greater than 50% is the constituent of greatest proportion in the layer or material). The term substantially pure indicates the constituent is not less than 99% of the material. The term pure indicates the constituent is not less than 99.5% of the material and the term completely pure indicates the constituent is not less than 99.9% of the material. As used herein, the terms “monolithic”, “monolithically integrated”, and similar terms indicate the components of the monolithic overall structure form an indivisible whole not reasonably capable of being separated.

As used throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. Additional terms are defined herein below.

As discussed, thermal management of multichip composite devices is a problem that, if not addressed, can cause damage to a device or undesirable device throttling. For example, in multichip composite devices that deploy an inorganic dielectric material fill (e.g., a silicon dioxide fill) between IC dies of the multichip composite device, the IC dies are thinned to a thickness of, for example, 10 to 15 microns. This IC die thinning enables use of inorganic dielectric material fill by making the oxide fill process reasonable in terms of process time and effort. Notably, for thicker dies, use of inorganic dielectric material is often not practicable. However, the bulk silicon of the IC dies transfers the majority of heat from the IC die during use, and losing the bulk silicon causes difficulty in removing heat.

In some embodiments, a microelectronic device includes a multichip composite device that includes a base die and a number of integrated circuit (IC) dies attached to the base die. As used herein, the term microelectronic device indicates a device including one or more integrated circuits to provide one or more functions. The microelectronic device may be at any level such as a packaged device, an assembly, a motherboard, or a consumer product. The term multichip composite device indicates a device having a number of chips or dies that are integrated and formed into a quasi-monolithic structure. For example, a quasi-monolithic structure may have quasi-monolithic hierarchical integration of IC dies that couples base dies, IC dies or chiplets, and the like to form a composite structure of a processing system. Notably, the term composite indicates the structure has multiple components such as active dies, and dielectric material on and between the active dies.

Furthermore, a handle die or structural member may be attached to the multichip composite device, and the handle die or handle layer may be part of the quasi-monolithic structure. As used herein the terms integrated circuit dies and chiplets indicate dies or chips having active circuitry (i.e., circuitry that is to provide electronic or device functionality when in operation). The term base die indicates a bottom level die that may or may not have active circuitry. For example, the base die, integrated circuit dies, and chiplets may include processor circuitry, memory circuitry, control circuitry, signal and power routing circuitry, and so on. The term integrated circuit die may be used as an umbrella term while the term base die may indicate an integrated circuit die deployed as a bottom or base layer die of the multichip composite device and the term chiplet may indicate an integrated circuit die deployed as a top or mid-level integrated circuit die of the multichip composite device. The terms handle die, structural member, lid, structural die, and structural silicon are used substantially interchangeably and indicate a structure that does not have such active circuitry. Instead, the structural member is to provide mechanical support, thermal routing, and other functionality for the quasi-monolithic structure or microelectronic device. Herein, the term handle die is largely used to describe the structural member, lid, structural die, and structural silicon. However, any such term may be used to characterized the structural element or member.

In some embodiments, the multichip composite device includes one or more IC dies or chiplets bonded to corresponding region(s) of a surface (i.e., a top surface) of a base die. The base die or dies may be at a base or zeroth layer of the multichip composite device and the IC dies bonded thereto may be at a first layer of the multichip composite device. Any number of additional layers of IC dies may be provided in the multichip composite device. For example, the one or more IC dies or chiplets may be bonded to the surface of the base die using hybrid bonding, and any number of IC die layers may be bonded in a stack using hybrid bonding. Hybrid bonding indicates bonding between surfaces that each include metallization (e.g., metal pads) interspersed with dielectric material. Bonds are formed between corresponding metallization and between corresponding dielectric material to form a wafer to wafer bond, die to wafer bond, or die to die bond. Such hybrid bonds may be performed using any techniques known in the art. In some embodiments, hybrid bonds include die-to-die interconnects with sub micrometer pitch. Furthermore, the multichip composite device includes inorganic dielectric material laterally adjacent to the one or more IC dies or chiplets, over a region of the base die, and/or laterally adjacent the base die. For example, the inorganic dielectric material may be formed over the hybrid bonded IC dies or chiplets and the base die to embed the IC dies or chiplets and the base die in the inorganic dielectric material. As used herein, the term inorganic dielectric material indicates materials not having carbon as a foundational component and being characterized as an electrical insulator. For example, an inorganic dielectric material may have a resistivity comparable to that of silicon dioxide. It is noted that such materials may include carbon as a dopant in some implementations. A structural member is provided over the stack to provide mechanical support and thermal routing.

A conformal heat spreading layer is provided on the IC dies at the highest implemented layer of IC dies over the base die. Herein, the term conformal indicates a layer or material has substantially the same thickness on all surfaces (horizontal, vertical, etc.) that the layer or material is on. In some embodiments, the conformal heat spreading layer is also on a region or regions of the base die. The conformal heat spreading layer has a thermal conductivity that is greater than that of the inorganic dielectric material and, in some embodiments, greater than that of the IC dies. The conformal heat spreading layer may be any material that is conducive to heat transfer and removal such as one or more metals (e.g., copper, aluminum, silver, or gold), diamond, graphene, graphite, or hexagonal boron nitride. Other high thermal conductivity materials may be deployed. The conformal heat spreading layer improves heat spreading and thermal performance of the top dies (e.g., IC dies at the highest layer of the multichip composite device), and the multichip composite device overall.

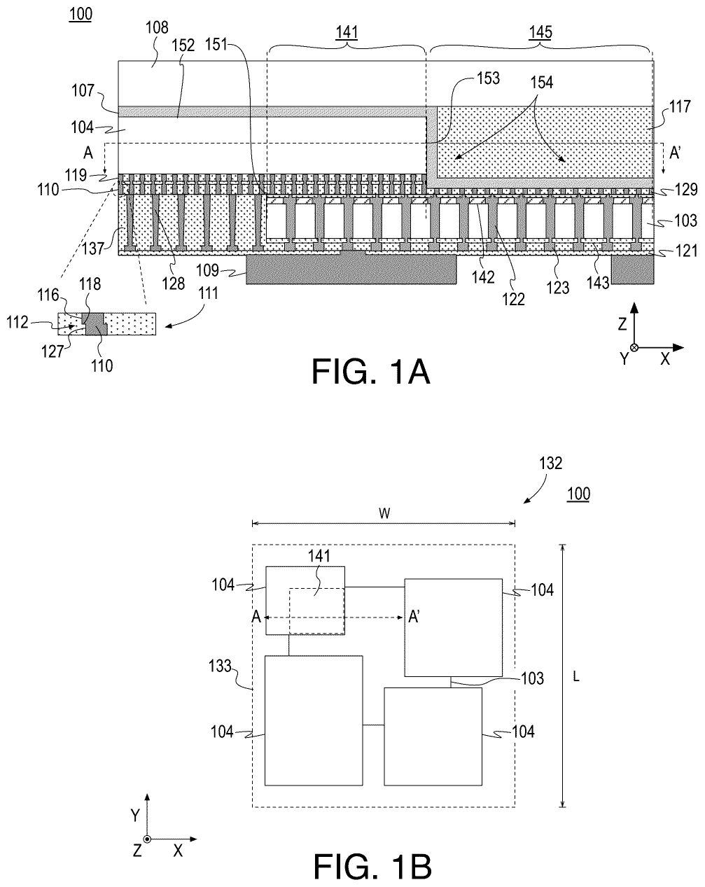

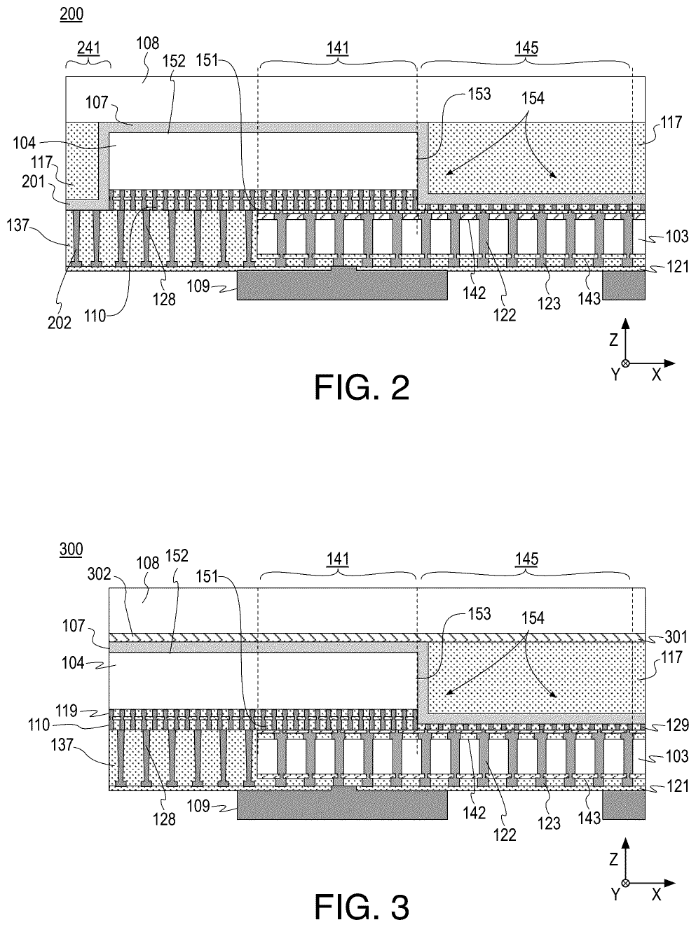

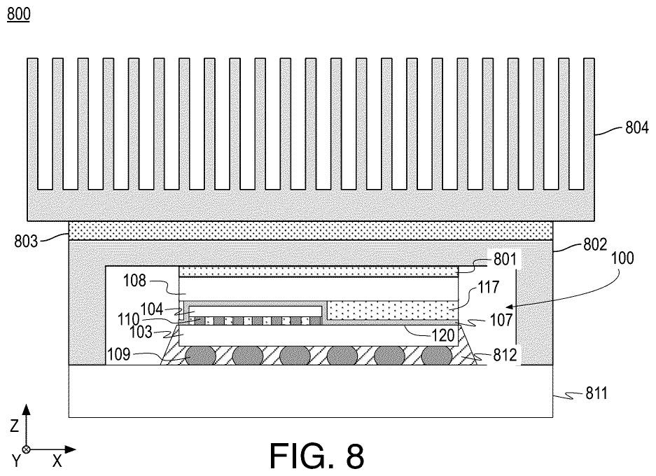

FIG. 1A illustrates a cross-sectional side view of a multichip composite device 100 including a conformal heat spreading layer 107 to provide a thermal pathway for heat removal from top IC dies 104, arranged in accordance with some embodiments. For example, multichip composite device 100 may be deployed in any microelectronic device. FIG. 1B illustrates an expanded cross-sectional plan view of the cross-section taken at plane A-A′ in FIG. 1A. As shown in FIG. 1A, multichip composite device 100 includes any number of IC dies 104 (which may be characterized as chiplets) coupled to a surface 142 of a base die 103 at shared bonding regions such as region 141. In some embodiments, base die 103 includes through vias 122 (e.g., through silicon vias, TSVs). As discussed, the terms IC die and chiplet indicate an active circuitry device (i.e., circuitry that is to provide computational functionality when in operation). For example, an IC die or chiplet may contain circuitry to perform a defined subset of functionality such as a memory chip, microprocessor, microcontroller, commodity IC (e.g., chip used for repetitive processing routines, simple tasks, application specific IC, etc.). The term base die also indicates an active circuitry device and may also be characterized as an IC die. For example, IC dies such as chiplets and base dies may be individual dies connected together to create the functionalities of a monolithic IC. As shown, base die 103 is at a lowest or base layer of multichip composite device 100. Furthermore, base die 103 is to interconnect, via interconnects 109 to a substrate (not shown). For example, interconnects 109 may be package level interconnects formed through a dielectric layer 121 to couple to a package substrate such as a package substrate, as discussed further herein below with respect to FIG. 8. As shown, interconnects 109 are adjacent a second surface 143 of base die 103 such that surface 143 is opposite surface 142. Interconnects 109 may be solder bumps or balls, interconnect posts or pads, interconnects formed from a conductive film or conductive paste, or the like.

IC dies 104 may be bonded to surface 142 of base die 103 using any suitable technique or techniques such as hybrid bonding to form die level interconnects 110. For example, die level metallization 119 may route to die level interconnects 110. In some embodiments, surfaces including metallization are interspersed among dielectric material may be formed on each of IC dies 104 and surface 142 of base die 103. In some embodiments, the patterning of the surfaces matches metal to metal and dielectric to dielectric for hybrid bonding between IC dies 104 and base die 103. Such surface may then be brought together optionally under pressure and/or heat to meld the metal to form die level interconnects 110 and, optionally, to meld the dielectric material to form the hybrid bond. As shown with respect to enlarged view 111, in some embodiments, die level interconnects 110 may include a misalignment 112 indicative of the hybrid bond.

Misalignment 112 may include, for example, a first sidewall 116 misaligned with a second sidewall 127 such that a lateral offset 118 (i.e., measured in the x-dimension) is therebetween. In some embodiments, lateral offset 118 is in the range of 10 to 200 nm. For example, lateral offset 118 may be not less than 10 nm, not less than 25 nm, or not less than 50 nm. Although any thicknesses may be used, in some embodiments, base die 103 may have a thickness between 15 and 50 microns, a thickness between 50 and 80 microns, or a thickness between 75 and 150 microns. In some embodiments, IC dies 104 have thicknesses between 10 and 15 microns.

IC dies 104 and base die 103 may include any suitable substrates and device components inclusive of semiconductor dies having a device layer and metallization layers fabricated using known semiconductor manufacturing processes. In some embodiments, the substrate is a substantially monocrystalline semiconductor, such as silicon or germanium; however other material systems may be deployed. The device layer may include any suitable devices such as transistors, capacitors, resistors, etc.

As shown in FIG. 1A, an inorganic dielectric material 137 is filled in laterally adjacent to base die 103 and/or between multiple base dies 103. As used herein, the term laterally adjacent indicates that an x-y plane intersects the two components that are laterally adjacent. In some embodiments, through vias 128 (e.g., through dielectric vias, TDVs) may extend through inorganic dielectric material 137. Inorganic dielectric material 117 may be any suitable inorganic dielectric material such as silicon dioxide, silicon oxynitride, carbon doped silicon dioxide, or the like.

Multichip composite device 100 includes region 141 of bottom surface 151 of IC die 104 hybrid bonded (e.g., to form die level interconnects 110) to region 141 of top surface 142 of base die 103 such that base die 103 has bottom surface 143, opposite top surface 142, is to interconnect to a substrate via interconnects 109. Conformal heat spreading layer 107 is on or over top surface 152 of IC die 104 such that top surface 152 is opposite bottom surface 151. In some embodiments, conformal heat spreading layer 107 is on an entirety of top surface 152 of IC die 104. Conformal heat spreading layer 107 is also on sidewall surface 153 of IC die 104 such that sidewall surface 153 extends vertically between top surface 152 and bottom surface 151 of IC die 104. As used herein, the term surface indicates the outside part or outermost surface of the pertinent component. It is noted that a surface may include a single material or subcomponent or multiple materials or subcomponents of the pertinent component. Furthermore, the term sidewall may indicate a sidewall that extends around a component or a sidewall that extends only along a portion of a perimeter of the component. As shown, conformal heat spreading layer 107 may also extend over region 145 of base die 103 and may be on and in contact with metal pads 129 that are coupled to or in contact with base die 103.

Multichip composite device 100 further includes inorganic dielectric material 117 on a portion 154 of conformal heat spreading layer 107 such that portion 154 may include a substantially vertical portion (i.e., along sidewall 153) and a substantially horizontal portion (e.g., on or over region 145 of base die 103). Inorganic dielectric material 117 is also over region 145 of base die 103. Inorganic dielectric material 117 may include any material discussed with respect to inorganic dielectric material 137. Handle die 108 (e.g., a structural member) is coupled to conformal heat spreading layer 107 either directly (as shown) or with one or more materials therebetween.

As discussed, conformal heat spreading layer 107 provides for an efficient thermal pathway for removal of heat from thinned IC die 104. In addition, conformal heat spreading layer 107 may provide an efficient thermal pathway from base die 103 via, for example, contacting metal pads 129 or base die 103 directly. Notably, conformal heat spreading layer 107 has a greater thermal conductivity than inorganic dielectric material 117 and/or IC die 104 for an improved thermal pathway. Handle die 108 provides mechanical robustness during processing, packaging, and so on, and handle die 108 aids in heat spreading and heat removal from IC dies 104 and base die 103 to a thermal solution, which is illustrated herein below.

As shown in FIG. 1B, where inorganic dielectric material 117 and conformal heat spreading layer 107 are not shown for the sake of clarity of presentation, IC dies 104 and dummy dies 105 may be arrayed over base die 103 in any suitable configuration to form a complex 132 having an area defined by edges 123 thereof. For example, complex 132 may have an area defined by a width W and a length L. In some embodiments, IC dies 104 are arranged entirely within the defined area such that no edge of IC dies 104 extends beyond edges 133 of complex 132. In some embodiments, handle die 108 substantially shares the area (W×L) and defines complex 132. In some embodiments, base die 103 also shares the area (W×L) such that edges of handle die 108 and the edges of base die 103 are substantially vertically aligned. For example, fabrication of base die 103 and handle die 108 may be performed at the wafer level (with IC dies 104 attached to the base die wafer using die to wafer attachment), and the overall structure may be diced such that shared edges between base die 103 and handle die 108 are formed (i.e., such that their outer edges are vertically aligned).

Returning to FIG. 1A, conformal heat spreading layer 107 is formed over IC dies 104 and regions of base die 103 in locations where IC dies 104 are absent for improved thermal conductivity pathways. Conformal heat spreading layer 107 may include any material or materials having a greater thermal conductivity than that of inorganic dielectric material 117 and/or IC die 104. For example, inorganic dielectric material 117 may be silicon dioxide (e.g., thermal conductivity of about 1.3 W/m-K) and IC die may be substantially crystalline silicon (e.g., thermal conductivity of about 120 W/m-K). In some embodiments, conformal heat spreading layer 107 includes or is a material that has a thermal conductivity of not less than 50 times, 100 times, or 200 times that of inorganic dielectric material 117.

In some embodiments, conformal heat spreading layer 107 is or includes a metal. In some embodiments, conformal heat spreading layer 107 is or includes copper, aluminum, silver, or gold. In some embodiments, conformal heat spreading layer 107 is or includes copper. In some embodiments, conformal heat spreading layer 107 is or includes copper having a thermal conductivity of not less than 400 W/m-K. In some embodiments, conformal heat spreading layer 107 is or includes aluminum. In some embodiments, conformal heat spreading layer 107 is or includes aluminum having a thermal conductivity of not less than 85 W/m-K. In some embodiments, conformal heat spreading layer 107 is or includes silver. In some embodiments, conformal heat spreading layer 107 is or includes silver having a thermal conductivity of not less than 400 W/m-K. In some embodiments, conformal heat spreading layer 107 is or includes gold. In some embodiments, conformal heat spreading layer 107 is or includes gold having a thermal conductivity of not less than 275 W/m-K. Combinations of such materials may be used. Furthermore, conformal heat spreading layer 107 may include a multilayer stack including, for example, an adhesion layer (e.g., silicon nitride for adhesion to a crystalline silicon top surface 152 of IC die 104), a barrier layer (e.g., tantalum, tantalum nitride, titanium, or titanium nitride to contain copper), and/or a seed layer (e.g., titanium, titanium nitride, or nickel vanadium). In some embodiments, particularly when electrical grounding is deployed using conformal heat spreading layer 107, such metals may be advantageous due to their electrical conductivity. For example, when conformal heat spreading layer 107 may also be used for electrical connection such as a grounding plane. In some embodiments, conformal heat spreading layer 107 may be used in RF (radio frequency) isolation or as an EMI (electromagnetic interference) shield.

In addition or in the alternative, conformal heat spreading layer 107 is or includes crystalline or polycrystalline diamond. In some embodiments, conformal heat spreading layer 107 is or includes crystalline or polycrystalline diamond having a thermal conductivity of not less than 1,000 W/m-K. In some embodiments, conformal heat spreading layer 107 is or includes crystalline or polycrystalline diamond having a thermal conductivity of not less than 2,000 W/m-K. For example, a crystalline or polycrystalline diamond may be applied using chemical vapor deposition (CVD). In some embodiments, conformal heat spreading layer 107 includes a layer of crystalline or polycrystalline diamond and a layer of metal thereon.

In some embodiments, conformal heat spreading layer 107 is or includes a material to promote lateral heat spreading. For example, conformal heat spreading layer 107 multilayer graphene, graphite or hexagonal boron nitride. In some embodiments, conformal heat spreading layer 107 is or includes one or more layers of graphene (e.g., atoms of carbon arranged in a 2D lattice such as a honeycomb lattice). In some embodiments, conformal heat spreading layer 107 is or includes graphite (e.g., crystalline or polycrystalline carbon). In some embodiments, conformal heat spreading layer 107 is or includes a compound of boron and nitrogen such as hexagonal boron nitride (e.g., crystalline or polycrystalline boron nitride). In some embodiments, conformal heat spreading layer 107 includes one or more layers of such materials and a layer of metal thereon. In some embodiments, particularly when electrical grounding is deployed using conformal heat spreading layer 107, multilayer graphene may be advantageous as it is electrically conductive.

Other materials may be used. In some embodiments, conformal heat spreading layer 107 is or includes boron and arsenic (i.e., a compound including boron and arsenic, boron arsenide). In some embodiments, conformal heat spreading layer 107 is or includes boron and arsenic having a thermal conductivity of not less than 1,300 W/m-K. In some embodiments, conformal heat spreading layer 107 is or includes silicon and carbon (i.e., a compound including silicon and carbon, silicon carbide). In some embodiments, conformal heat spreading layer 107 is or includes silicon and carbon having a thermal conductivity of not less than 490 W/m-K. In some embodiments, conformal heat spreading layer 107 is or includes aluminum and nitrogen (i.e., a compound including aluminum and nitrogen, aluminum nitride). In some embodiments, conformal heat spreading layer 107 is or includes aluminum and nitrogen having a thermal conductivity of not less than 320 W/m-K. Other high thermal conductivity material layers may be used.

A relatively thin layer (i.e., total thickness) of conformal heat spreading layer 107 may be used due to the high thermal conductivity of the material(s). In some embodiments, conformal heat spreading layer 107 has a thickness in the range of 50 nm to 2 microns. In some embodiments, conformal heat spreading layer 107 has a thickness in the range of 50 nm to 500 nm. In some embodiments, a thickness of conformal heat spreading layer 107 is not more than 500 nm. In some embodiments, a thickness of conformal heat spreading layer 107 is not more than 250 nm. As discussed, in some embodiments, conformal heat spreading layer 107 may include any material or materials having a greater thermal conductivity that that of IC die 104. In some embodiments, the material or composite of materials of conformal heat spreading layer 107 has a thermal conductivity of not less than twice the thermal conductivity of IC die 104. In some embodiments, the material or materials of conformal heat spreading layer 107 has a thermal conductivity of not less than five times the thermal conductivity of IC die 104. In some embodiments, the material or materials of conformal heat spreading layer 107 has a thermal conductivity of not less than seven times the thermal conductivity of IC die 104.

In some embodiments, thermal management may be further enhanced by contacting conformal heat spreading layer 107 to through vias 128. For example, conformal heat spreading layer 107 may be thermally coupled to through vias 122 (e.g., TSVs) to provide a thermal pathway from base die 103. In addition or in the alternative, conformal heat spreading layer 107 may be thermally coupled to through vias 128 (e.g., TDVs) to provide a heat removal path of the multichip composite device.

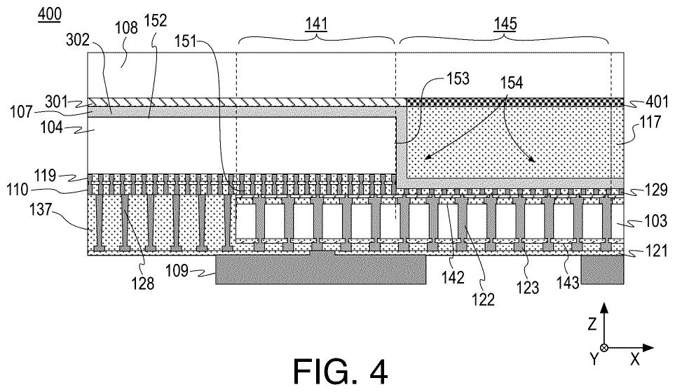

FIG. 2 illustrates a cross-sectional side view of a multichip composite device 200 including conformal heat spreading layer 107 having a portion 201 in contact with a base layer level through dielectric via 202, arranged in accordance with some embodiments. For example, multichip composite device 200 may be deployed in any microelectronic device. In FIG. 2, and elsewhere herein, like components are labeled with like numerals and such components may have any characteristics discussed herein. For example, multichip composite device 200 is similar to multichip composite device 100 with the exception that a portion of is on one or more through vias 202 of through vias 128. As discussed with respect to FIG. 1A, inorganic dielectric material 137 is filled in laterally adjacent to base die 103 and/or between multiple base dies 103, such that inorganic dielectric material 137 may be characterized as a base layer or level inorganic dielectric. Through vias 128 (e.g., TDVs) may extend through inorganic dielectric material 137. Such through vias 128 may provide electrical routing between IC die 104 and interconnects 109, for example.

In some embodiments, one or more through vias 202 are in contact with portion 201 of conformal heat spreading layer 107 to provide increased thermal pathways in multichip composite device 200. In some embodiments, conformal heat spreading layer 107 is on inorganic dielectric material 137, and on one or more through vias 202 embedded in inorganic dielectric material 137. As shown, through vias 202 and inorganic dielectric material 137 are laterally adjacent the base die. Inorganic dielectric material 137 may be any material discussed above. Inorganic dielectric material 137 and inorganic dielectric material 117 may be the same or they may be different. Conformal heat spreading layer 107 may have any characteristics discussed herein such that conformal heat spreading layer 107 includes portion 201 on inorganic dielectric material 137 and on one or more through vias 202 in a region 241. As shown, region 241 may be immediately adjacent IC die 104.

As discussed, in some embodiments, handle die 108 is on and attached to at least a portion of conformal heat spreading layer 107. Handle die 108 may also be on and attached to a portion of inorganic dielectric material 137. In some embodiments, a metal layer is provided on handle die 108 prior to attachment to aid in direct bonding, and to provide a thermal pathway to handle die 108, and any thermal solution provided above handle die 108.

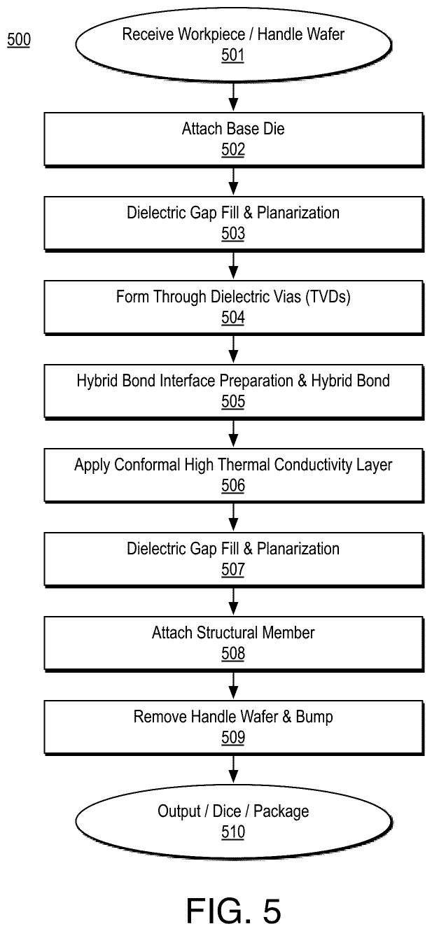

FIG. 3 illustrates a cross-sectional side view of a multichip composite device 300 including an intervening metal layer 301 between conformal heat spreading layer 107 and handle die 108, arranged in accordance with some embodiments. Multichip composite device 300 may be deployed in any microelectronic device. For example, multichip composite device 300 is similar to multichip composite device 100 with the exception that metal layer 301 is provided between handle die 108 and a portion 302 of conformal heat spreading layer 107 and between handle die 108 and portions of inorganic dielectric material 117.

Notably, during fabrication, as discussed further herein below, metal layer 301 may be deposited on handle die 108 (either as a die or as a wafer during processing, prior to dicing) to aid both bonding (e.g., by providing a metal to metal bond with portion 302 of conformal heat spreading layer 107) and heat transfer (e.g., by providing a high thermal conductivity pathway to handle die 108). For example, portion 302 of conformal heat spreading layer 107 and metal layer 301 may provide heat transfer medium between the silicon (or other substrate material) of IC die 104 and the silicon (or other substrate material) of handle die 108.

Metal layer 301 may include any suitable metal for boding to conformal heat spreading layer 107, which may also include a metal layer on metal layer 301. In some embodiments, metal layer 301 is or includes copper, aluminum, silver, or gold. In some embodiments, metal layer 301 is or includes copper, for example, having a thermal conductivity of not less than 400 W/m-K. In some embodiments, metal layer 301 is or includes aluminum, for example, having a thermal conductivity of not less than 85 W/m-K. In some embodiments, metal layer 301 is or includes silver, for example, having a thermal conductivity of not less than 400 W/m-K. In some embodiments, metal layer 301 is or includes gold, for example, having a thermal conductivity of not less than 275 W/m-K. Combinations of such materials may be used. In some embodiments, metal layer 301 has the same material as the entirety of conformal heat spreading layer 107 or a layer of metal of conformal heat spreading layer 107 that is adjacent metal layer 301.

As discussed, metal layer 301 may increase bonding between handle die 108 and the remainder of multichip composite device 300. In particular, a metal to metal bond between metal layer 301 and conformal heat spreading layer 107 may advantageously increase the bond strength in multichip composite device 300. Furthermore, metal layer 301 may improve the thermal pathways in multichip composite device 300 for more efficient heat removal. However, the increased thermal pathway may come at the cost of a relatively weak bond between metal layer 301 and inorganic dielectric material 117.

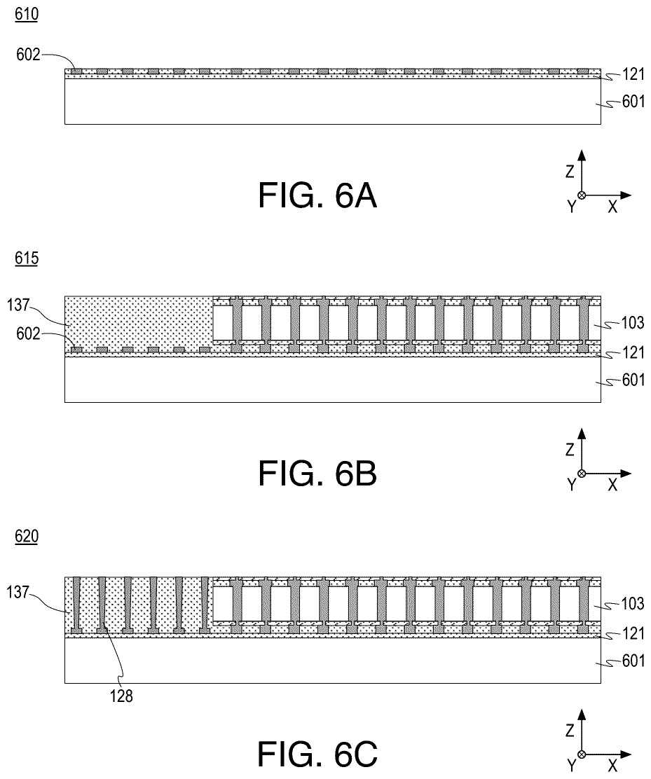

FIG. 4 illustrates a cross-sectional side view of a multichip composite device 400 including selective intervening metal and dielectric layers 301, 401 between handle die 108 and conformal heat spreading layer 107 and inorganic dielectric material 117, arranged in accordance with some embodiments. Multichip composite device 400 may be deployed in any microelectronic device. For example, multichip composite device 400 is similar to multichip composite device 300 with the exception that metal layer 301 is provided selectively only between handle die 108 and portion 302 of conformal heat spreading layer 107, while an inorganic dielectric layer 401 is provided between handle die 108 and portions of inorganic dielectric material 117.

During fabrication, as discussed further herein, metal layer 301 may be patterned within inorganic dielectric layer 401 (e.g., using damascene techniques or other deposition and patterning techniques) on handle die 108 (or a handle wafer corresponding to handle die 108, prior to dicing). Metal layer 301 aids in bonding to portion 302 of conformal heat spreading layer 107, as well as heat transfer by providing a high thermal conductivity pathway to handle die 108. Inorganic dielectric layer 401 aids in bonding to corresponding inorganic dielectric material 117. It is noted that some heat transfer pathway is lost in this implementation relative to multichip composite device 300.

Metal layer 301 may include any suitable metal for boding to portion 302 of conformal heat spreading layer 107 such as copper aluminum, silver, or gold with copper to copper bonding being particularly advantageous. Similarly, inorganic dielectric layer 401 may be any material discussed with respect to inorganic dielectric material 117 such as silicon dioxide, silicon oxynitride, or carbon doped silicon dioxide. Inorganic dielectric layer 401 and inorganic dielectric material 117 may be the same materials or they may be different.

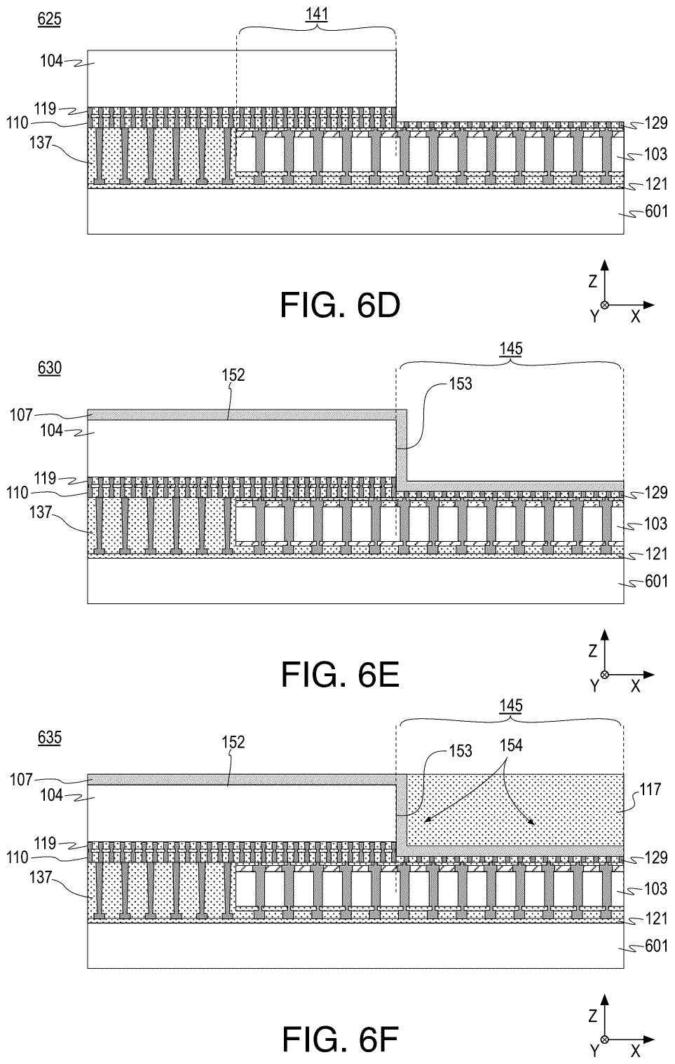

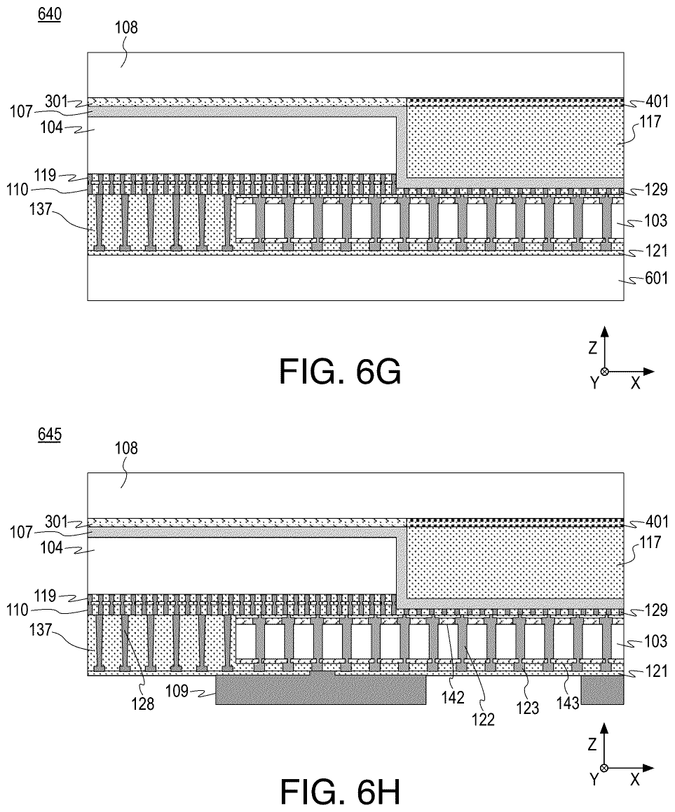

FIG. 5 is a flow diagram illustrating an example process 500 for forming a multichip composite device including a conformal heat spreading layer 107 to provide a thermal pathway for heat removal from IC dies of the multichip composite device, arranged in accordance with some embodiments. FIGS. 6A, 6B, 6C, 6D, 6E, 6F, 6G, and 6H illustrate cross-sectional side views of multichip composite device structures as the operations of process 500 are performed, arranged in accordance with some embodiments. For example, process 500 may be used to fabricate any of multichip composite devices 100, 200, 300, or 400, and process 500 may be extended to fabricate multichip composite device 700. As shown, process 500 begins at operation 501, where a workpiece or handle wafer is received for processing. The handle wafer may be any suitable substrate material such as a crystalline silicon wafer. The handle wafer may be preprocessed to form exposed metal bond pads embedded in a dielectric layer for subsequent micro-bonding.

FIG. 6A illustrates an example multichip composite device structure 610. As shown, multichip composite device structure 610 includes dielectric layer 121 and metal pads 602 (or microbumps) arrayed within dielectric layer 121 over handle wafer 601. Dielectric layer 121 may include any suitable dielectric material such as silicon dioxide formed using any suitable technique or techniques. Metal pads 602 may include any suitable conductive material such as copper or other metal. In some embodiments, metal pads 602 are formed using damascene techniques inclusive of depositing dielectric layer 121, patterning dielectric layer 121 to form holes (e.g., using lithography and etch techniques), filling the holes with metal, and subsequent planarization techniques.

Returning to FIG. 5, processing continues at operation 502, where one or more base dies are attached to the metal bond pads. The base die(s) may be attached using any suitable technique or techniques In some embodiments, microbumps are formed on the base die and the microbumps are aligned with and brought into contact with the metal bond pads under heat to at least partially meld the microbumps and the metal bond pads. For example, the base dies may be attached using micro-bumping and bonding techniques. Processing continues at operation 503, where dielectric gap fill and planarization processing are performed to provide inorganic dielectric material laterally adjacent to the one or more base dies and to expose the base dies for further processing. The gap fill processing may be performed using any suitable material deposition techniques. The planarization processing may be performed using any suitable technique or techniques. Notably, the base die attach may be performed in a die to wafer manner and the deposition and planarization processes may be performed at the wafer level.

FIG. 6B illustrates an example multichip composite device structure 615 similar to multichip composite device structure 610 after die attach and dielectric gap fill processing. As shown, one or more base dies 103 are coupled to some of metal pads 602 while others of metal pads 602 are left exposed. Base die 103 may have any characteristics discussed herein. Also as shown, inorganic dielectric material 137 is formed laterally adjacent to base die 103. Inorganic dielectric material 137 may include any suitable material or materials such as silicon dioxide, silicon oxynitride, carbon doped silicon dioxide, or the like. After planarization processing, a top surface of inorganic dielectric material 137 and a top surface of one or more base dies 103 are substantially planar.

Returning to FIG. 5, processing continues at operation 504, where through dielectric vias (TDVs) are formed in the inorganic dielectric material laterally adjacent to the base die(s). The TDVs may be formed using any suitable technique or techniques. In some embodiments, photolithography techniques are used to form a patterned resist layer over the inorganic dielectric material and the base die(s) such that only portions of the surface that are exposed are those where TDVs are to be formed. Etch techniques are then used to form holes at the TDV locations. The patterned resist layer is then removed and the holes may be filled with metal using any suitable technique or techniques such as metal seeding and electroplating techniques. A planarization operation may then be performed to remove portions of the deposited metal, leaving the TDVs.

FIG. 6C illustrates an example multichip composite device structure 620 similar to multichip composite device structure 615 after the formation of through vias 137 embedded in inorganic dielectric material 137. Through vias 137 may include any suitable material such as a copper fill within a barrier layer such as a titanium, titanium nitride, tantalum, or tantalum nitride barrier layer. Through vias 137 may be provided at any suitable density to providing signal or power or the like.

Returning to FIG. 5, processing continues at operation 505, where hybrid bonding interface preparation and hybrid bonding are performed. In some embodiments, hybrid bonding interface preparation includes forming exposed metal pads within a dielectric layer on both the wafer being processed and those dies that are to be hybrid bonded. The metal pads include corresponding patterns such that, when brought together, metal-to-metal and dielectric-to-dielectric contacts are made. Under pressure and optionally at an elevated temperature, bonds are formed at the metal-to-metal interfaces and the dielectric-to-dielectric interfaces to form the hybrid bond.

FIG. 6D illustrates an example multichip composite device structure 625 similar to multichip composite device structure 620 after hybrid bonding IC die 104 to region 141 of base die 103 and to one or more of through vias 137. For example, through vias 137 may provide routing to IC die 104. In some embodiments, die level metallization 119 provide routing to die level interconnects 110 formed during the hybrid bonding.

Returning to FIG. 5, processing continues at operation 506, where a conformal high thermal conductivity layer is formed on the one or more IC dies and exposed portions of the base die or metal pads in thermal communication with the base die. The conformal high thermal conductivity layer may be formed using any suitable technique or techniques, depending on the material being applied. Such techniques are inclusive of one or more of electroplating, chemical vapor deposition (CVD), and others.

FIG. 6E illustrates an example multichip composite device structure 630 similar to multichip composite device structure 625 after the formation of conformal heat spreading layer 107 on exposed top surface 152 of IC die 104 and exposed sidewall surface 153 of IC die 104. Conformal heat spreading layer 107 is also formed over region 145 of base die 103. Conformal heat spreading layer 107 may have any characteristics discussed herein. For example, conformal heat spreading layer 107 may include one or more of a metal such as copper, aluminum, silver, or gold, crystalline or polycrystalline diamond, one or more layers of graphene, graphite, hexagonal boron nitride, or any other material discussed with respect to conformal heat spreading layer 107 herein.

Returning to FIG. 5, processing continues at operation 507, where dielectric gap fill and planarization are performed to provide inorganic dielectric material laterally adjacent to the one or more IC dies and to expose a portion of the conformal heat spreading layer. The gap fill processing may include deposition techniques and the planarization processing may remove a top portion of the deposited inorganic dielectric material to the portion of the conformal heat spreading layer, and provide a substantially planar top surface.

FIG. 6F illustrates an example multichip composite device structure 635 similar to multichip composite device structure 630 after dielectric gap fill processing. As shown, inorganic dielectric material 117 is formed laterally adjacent to IC die 104 and on portion 154 of conformal heat spreading layer 107. As discussed, portion 154 may include a substantially vertical portion (i.e., on sidewall 153) and a substantially horizontal portion (e.g., on or over region 145 of base die 103). Inorganic dielectric material 117 may include any suitable material or materials such as silicon dioxide, silicon oxynitride, carbon doped silicon dioxide, or the like. Inorganic dielectric material 117 and inorganic dielectric material 137 may be the same or they may be different. After planarization processing, a top surface of inorganic dielectric material 117 and a top surface of portion 302 of conformal heat spreading layer 107 are substantially planar, and prepared for attachment of a structural member or handle die.

Returning to FIG. 5, processing continues at operation 508, where a handle die or structural member is attached to the top surface of the multichip composite device structure. The structural member may be attached using any suitable technique or techniques. In some embodiments, the structural member is attached at a wafer level using wafer-to-wafer bonding techniques. In some embodiments, the structural member is attached as a die to a wafer (i.e., in a die-to-wafer manner). In some embodiments, the structural member is brought into contact with the multichip composite device structure and bonded optionally using heat and pressure. As discussed, in some embodiments, the structural member includes a metal layer for improved metal-to-metal bonding. In some embodiments, the structural member includes surface having patterned metal and dielectric to match that of multichip composite device structure for improved metal-to-metal bonding and improved dielectric-to-dielectric bonding.

FIG. 6G illustrates an example multichip composite device structure 640 similar to multichip composite device structure 635 after attachment of handle die 108 (i.e., a structural member) to the exposed top surface of multichip composite device structure 635. In the illustrated embodiment, a patterned metal layer 301 and inorganic dielectric layer 401 are provided such that the pattern matches that of portion 154 of conformal heat spreading layer 107 and inorganic dielectric material 117, respectively. Such techniques may provide improved bonding. However, handle die 108 may be bonded to form the structures of multichip composite device 100, 200, 300 using the same or similar techniques. In some embodiments, handle die 108 is attached as a portion of a handle wafer, which is used as a support structure for later processing, and handle die may be diced from the handle wafer.

Returning to FIG. 5, processing continues at operation 509, where the original handle wafer is removed and interconnects are formed on the multichip composite device structure for eventual attachment to a substrate such as a package substrate, board, etc. The handle wafer may be removed using any suitable technique or techniques such as back side grind techniques, back side etch techniques, laser based detachment, or the like. The interconnects may be formed using any suitable technique or techniques such as bumping techniques, metal deposition and patterning techniques, or the like.

FIG. 6H illustrates an example multichip composite device structure 645 similar to multichip composite device structure 640 after removal of handle wafer 601 and the formation of interconnects 109. For example, removal of handle wafer 601 may be characterized as a back side reveal. Interconnects 109 may include any interconnects discussed herein such as bumps, pillars, pads, or the like for eventual connection to an external substrate.

Returning to FIG. 5, processing continues at operation 510, where the resultant multichip composite device structure may be output and/or further processed. For example, the multichip composite device structure may be diced into individual components and packaged using techniques known in the art. In some embodiments, the multichip composite device structure is packaged to form the microelectronic device assembly illustrated with respect to FIG. 8. However, the multichip composite device structure may be implemented in any suitable form factor device.

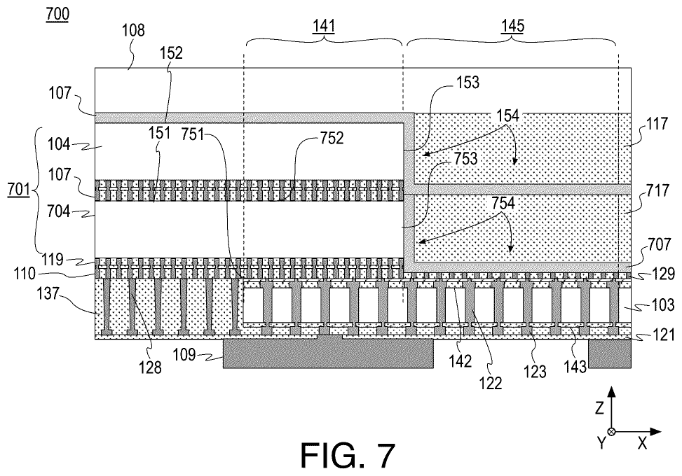

FIG. 7 illustrates a cross-sectional side view of a multichip composite device 700 including a conformal heat spreading layer 107 over a multilevel IC die stack 701 to provide a thermal pathway for heat removal from top IC dies 104, arranged in accordance with some embodiments. For example, multichip composite device 100 may be deployed in any microelectronic device. Multichip composite device 700 includes any number of IC dies 104, 704 (e.g., chiplets) such that IC dies 704 are in a first layer over base die 103 and IC dies 104 are in a second layer over the first layer. Although illustrated with respect to two layers in multilevel IC die stack 701, any number such as three, four, or more may be used.

As shown, any number of first level IC dies 704 are coupled to surface 142 of base die 103 at shared bonding regions 141. Furthermore, any number of second, third, and so on IC dies 104 are hybrid bonded to other IC dies in multilevel IC die stack 701. IC dies 704 may include any suitable substrates and device components as discussed with respect to IC dies 104. As shown in FIG. 7, inorganic dielectric material 137 is laterally adjacent to base die 103 and/or between multiple base dies 103, inorganic dielectric material 717 is laterally adjacent IC die 704, and inorganic dielectric material 117 is laterally adjacent IC die 104. The same is true for any number of IC die/inorganic dielectric material layers therebetween. Inorganic dielectric material 717 (and other intervening inorganic dielectric material layers) may be any suitable inorganic dielectric material such as silicon dioxide, silicon oxynitride, carbon doped silicon dioxide, or the like.

Notably, in fabrication, conformal heat spreading layer 707 may be formed on top surface 752 (opposite bottom surface 751 of IC die 704) and sidewall surface 753 of IC die 704. Inorganic dielectric material 717 is then deposited and planarization is performed such that conformal heat spreading layer 707 is removed from top surface 752 but remains on sidewall surface 753. Subsequent to the inorganic dielectric material deposit and planarization, any number of IC dies and corresponding conformal heat spreading layers/inorganic dielectric material layers are included in multilevel IC die stack 701 in a similar manner Subsequently, IC die 104 is hybrid bonded to IC die 704 (or a top most IC die). Conformal heat spreading layer 107 is then formed and processing continues as discussed with respect to FIGS. 6E, 6E, 6G, and 6H. Conformal heat spreading layer 707 may have any characteristics discussed with respect to conformal heat spreading layer 107. For example, conformal heat spreading layer 707 may include one or more of a metal such as copper, aluminum, silver, or gold, crystalline or polycrystalline diamond, one or more layers of graphene, graphite, hexagonal boron nitride, or any other material discussed with respect to conformal heat spreading layer 107.

Multichip composite device 700 includes base die 103 having bottom surface 143 to interconnect to a substrate (not shown), multilevel IC die stack 701 of one or more IC dies 104, 704 over region 141 of top surface 142 of base die 103, conformal heat spreading layer 107 on top surface 152 of the uppermost IC die 104 of multilevel IC die stack 701, and on surface 153 of the uppermost IC die 104, inorganic dielectric material 117 on portion 154 of conformal heat spreading layer 107 such that inorganic dielectric material 117 is over region 145 of top surface 142 of base die 103 and laterally adjacent sidewall surface 153 of uppermost IC die 104 such that conformal heat spreading layer 107 has a greater thermal conductivity than inorganic dielectric material 117 and/or uppermost IC die 104.

As discussed, inorganic dielectric material 117 is on portion 154 of conformal heat spreading layer 107. In a similar manner, inorganic dielectric material 717 is on portion 754 of conformal heat spreading layer 707 such that portion 754 may include a substantially vertical portion (i.e., along sidewall 753) and a substantially horizontal portion (e.g., on or over region 145 of base die 103). Inorganic dielectric material 717 is also over region 145 of base die 103. Handle die 108 (e.g., a structural member) is coupled to conformal heat spreading layer 107 either directly (as shown) or with one or more materials therebetween as discussed with respect to FIGS. 3 and 4.

Conformal heat spreading layers 107, 707 provide for an efficient thermal pathway for removal of heat from IC die 104 and IC die 704. In addition, conformal heat spreading layers 107, 707 may provide an efficient thermal pathway from base die 103 via, for example, conformal heat spreading layers 707 contacting metal pads 129 or base die 103 directly. Notably, conformal heat spreading layers 107, 707 each have a greater thermal conductivity than inorganic dielectric materials 117, 717 and/or IC dies 104, 704 for an improved thermal pathway.

FIG. 8 illustrates an example microelectronic device assembly 800 including a conformal heat spreading layer over IC dies of a multichip composite device for improved thermal conductivity pathways, in accordance with some embodiments. In the illustrative example of FIG. 8, multichip composite device 100 is represented. However, any multichip composite device, microelectronic device, or the like discussed herein may be deployed in microelectronic device assembly 800. As shown, microelectronic device assembly 800 includes base die 103 attached to a substrate 811 via interconnects 109, and an optional underfill 812. As discussed, IC dies 104 are bonded to base die 103 by interconnects 110, and inorganic dielectric material 117 is provided adjacent IC dies 104. In the context of FIG. 8, multichip composite device 100 also conformal heat spreading layer 107 and handle die 108. However other heat removal enhancement discussed herein may be used in the context of microelectronic device assembly 800. Microelectronic device assembly 800 may include a power supply (not shown) coupled to one or more of base die 103, IC dies 104, or other components of microelectronic device assembly 1200. The power supply may include a battery, voltage converter, power supply circuitry, or the like.

Microelectronic device assembly 800 further includes a thermal interface material (TIM) 801 disposed on a top surface of handle die 108. TIM 801 may include any suitable thermal interface material and may be characterized as TIM L Integrated heat spreader 802 having a surface on TIM 801 extends over multichip composite device 100, and is mounted to substrate 811. Substrate 811 may include any suitable substrate such as a package substrate, motherboard, interposer, or the like. In addition or in the alternative, substrate 811 may be mounted to a motherboard. Microelectronic device assembly 800 further includes TIM 803 disposed on a top surface of integrated heat spreader 802. TIM 803 may include any suitable thermal interface material and may be characterized as TIM 2. TIM 801 and TIM 803 may be the same materials or they may be different. Heat sink 804 (e.g., an exemplary heat dissipation device or thermal solution) is on TIM 803 and dissipates heat generated by base die 103. Although illustrated with respect to microelectronic device assembly 800, the various heat removal enhancements discussed herein may be deployed in any suitable architecture and form factor. For example, microelectronic device assembly 800 may be used in desktop and server form factors. In other contexts, a heat solution such as a heat pipe or heat spreader may be mounted directly on TIM 801. Such assemblies may be used in smaller form factor devices. Other heat dissipation devices may be used in concert with the heat removal enhancement structures discussed herein. As used herein, the term heat exchanger indicates a structure or device inclusive of any such heat removal solutions inclusive of integrated heat spreaders, heat sinks, heat pipes, and so on.

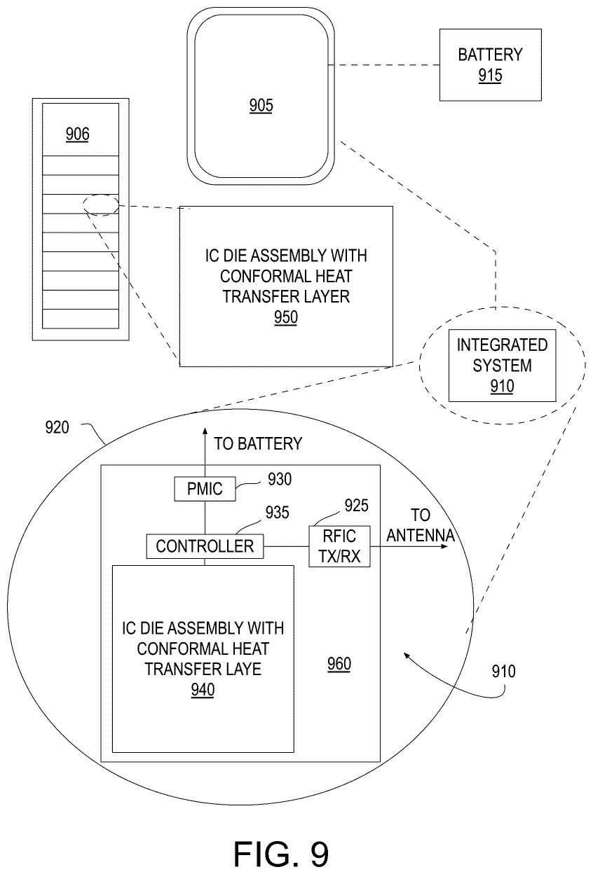

FIG. 9 illustrates exemplary systems employing an IC assembly including a conformal heat spreading layer over IC dies of a multichip composite device, in accordance with some embodiments. The system may be a mobile computing platform 905 and/or a data server machine 906, for example. Either may employ a component assembly including at least heat removal enhancement as described elsewhere herein. Server machine 906 may be any commercial server, for example including any number of high-performance computing platforms disposed within a rack and networked together for electronic data processing, which in the exemplary embodiment includes an IC die assembly 950 with a conformal heat spreading layer as described elsewhere herein. Mobile computing platform 905 may be any portable device configured for each of electronic data display, electronic data processing, wireless electronic data transmission, or the like. For example, mobile computing platform 905 may be any of a tablet, a smart phone, a laptop computer, etc., and may include a display screen (e.g., a capacitive, inductive, resistive, or optical touchscreen), a chip-level or package-level integrated system 910, and a battery 915. Although illustrated with respect to mobile computing platform 905, in other examples, chip-level or package-level integrated system 910 and a battery 915 may be implemented in a desktop computing platform, an automotive computing platform, an internet of things platform, or the like. As discussed below, in some examples, the disclosed systems may include a sub-system 960 such as a system on a chip (SOC) or an integrated system of multiple ICs, which is illustrated with respect to mobile computing platform 905.

Whether disposed within integrated system 910 illustrated in expanded view 920 or as a stand-alone packaged device within data server machine 906, sub-system 960 may include memory circuitry and/or processor circuitry 940 (e.g., RAM, a microprocessor, a multi-core microprocessor, graphics processor, etc.), a power management integrated circuit (PMIC) 930, a controller 935, and a radio frequency integrated circuit (RFIC) 925 (e.g., including a wideband RF transmitter and/or receiver (TX/RX)). As shown, one or more IC dice, such as memory circuitry and/or processor circuitry 940 may be assembled and implemented such that one or more have a heat removal enhancement as described herein. In some embodiments, RFIC 925 includes a digital baseband and an analog front end module further comprising a power amplifier on a transmit path and a low noise amplifier on a receive path). Functionally, PMIC 930 may perform battery power regulation, DC-to-DC conversion, etc., and so has an input coupled to battery 915, and an output providing a current supply to other functional modules. As further illustrated in FIG. 9, in the exemplary embodiment, RFIC 925 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 940 may provide memory functionality for sub-system 960, high level control, data processing and the like for sub-system 960. In alternative implementations, each of the SOC modules may be integrated onto separate ICs coupled to a package substrate, interposer, or board.

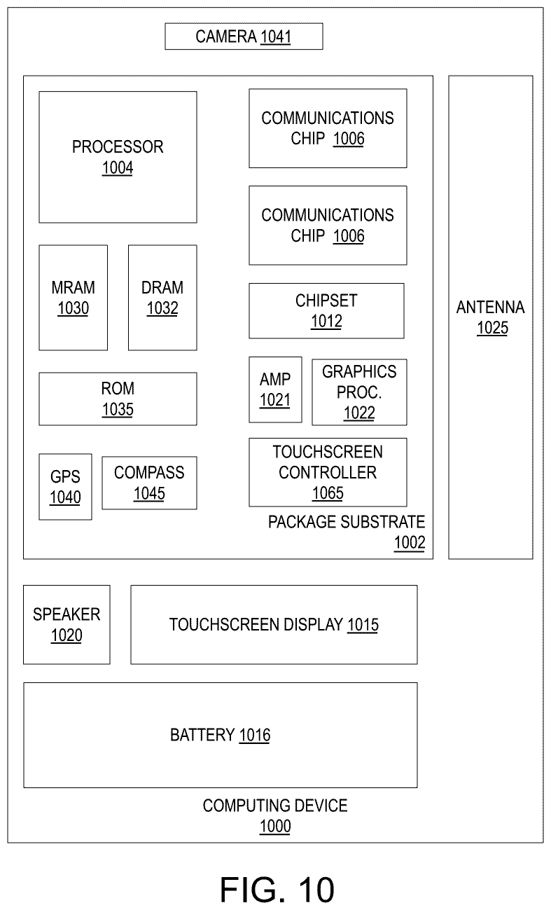

FIG. 10 is a functional block diagram of an electronic computing device 1000, in accordance with some embodiments. For example, device 1000 may, via any suitable component therein, employ a conformal heat spreading layer in accordance with any embodiments described elsewhere herein. Device 1000 further includes a motherboard or package substrate 1002 hosting a number of components, such as, but not limited to, a processor 1004 (e.g., an applications processor). Processor 1004 may be physically and/or electrically coupled to package substrate 1002. In some examples, processor 1004 is within an IC assembly that includes a heat removal enhancement as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 1006 may also be physically and/or electrically coupled to the package substrate 1002. In further implementations, communication chips 1006 may be part of processor 1004. Depending on its applications, computing device 1000 may include other components that may or may not be physically and electrically coupled to package substrate 1002. These other components include, but are not limited to, volatile memory (e.g., DRAM 1032), non-volatile memory (e.g., ROM 1035), flash memory (e.g., NAND or NOR), magnetic memory (MRAM 1030), a graphics processor 1022, a digital signal processor, a crypto processor, a chipset 1012, an antenna 1025, touchscreen display 1015, touchscreen controller 1065, battery 1016, audio codec, video codec, power amplifier 1021, global positioning system (GPS) device 1040, compass 1045, accelerometer, gyroscope, speaker 1020, camera 1041, and mass storage device (such as hard disk drive, solid-state drive (SSD), compact disk (CD), digital versatile disk (DVD), and so forth, or the like.

Communication chips 1006 may enable wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1006 may implement any of a number of wireless standards or protocols, including, but not limited to, those described elsewhere herein. As discussed, computing device 1000 may include a plurality of communication chips 1006. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example the above embodiments may include specific combinations of features as further provided below.

The following pertain to exemplary embodiments.

In one or more first embodiments, a multichip composite device comprises a first region of a bottom surface of an integrated circuit (IC) die hybrid bonded to a first region of a top surface of a base die, wherein a bottom surface of the base die, opposite the top surface of the base die, is to interconnect to a substrate, a conformal layer on a top surface of the IC die, opposite the bottom surface of the IC die, and on a sidewall surface of the IC die, the sidewall surface extending between the top and bottom surfaces of the IC die, an inorganic dielectric material on a portion the conformal layer, over a second region of the top surface of the base die, and laterally adjacent the sidewall surface of the IC die, wherein the conformal layer comprises a greater thermal conductivity than the inorganic dielectric material, and a structural member coupled to the conformal layer.

In one or more second embodiments, further to the first embodiments, the conformal layer is over the second region of the top surface of the base die and in contact with a metal pad coupled to the base die.

In one or more third embodiments, further to the first or second embodiments, the conformal layer is on a second inorganic dielectric material and one or more through dielectric vias (TDVs) embedded in the second inorganic dielectric material, wherein the second inorganic dielectric material and the one or more TDVs are laterally adjacent the base die.

In one or more fourth embodiments, further to the first through third embodiments, the conformal layer comprises a metal.

In one or more fifth embodiments, further to the first through fourth embodiments, the metal comprises one or more of copper, aluminum, silver, or gold.

In one or more sixth embodiments, further to the first through fifth embodiments, the conformal layer comprises one or more of diamond, graphene, graphite, or a compound of boron and nitrogen.

In one or more seventh embodiments, further to the first through sixth embodiments, the structural member is directly on the conformal layer.

In one or more eighth embodiments, further to the first through seventh embodiments, the conformal layer comprises a metal and a second metal layer is in contact with the conformal layer and in contact with the structural member.

In one or more ninth embodiments, further to the first through eighth embodiments, the second metal layer is between the structural member and the inorganic dielectric material.

In one or more tenth embodiments, further to the first through ninth embodiments, a second dielectric material laterally adjacent to the second metal layer is in contact with the inorganic dielectric material and in contact with the inorganic dielectric material.

In one or more eleventh embodiments, a multichip composite device comprises a base die comprising a bottom surface to interconnect to a substrate, a stack of one or more integrated circuit (IC) dies over a first region of a top surface of the base die, opposite the bottom surface of the base die, a conformal layer on a top surface of an uppermost one of the one or more IC dies and on a sidewall surface of the uppermost one of the IC dies, an inorganic dielectric material on a portion of the conformal layer, the inorganic dielectric material over a second region of the top surface of the base die, and laterally adjacent the sidewall surface of the uppermost IC die, wherein the conformal layer comprises a greater thermal conductivity than the inorganic dielectric material, and a structural member over the conformal layer.

In one or more twelfth embodiments, further to the eleventh embodiments, the one or more IC dies comprise the uppermost IC die hybrid bonded to a second one of the one or more IC dies, and wherein the conformal layer extends between the inorganic dielectric material and a second inorganic dielectric material laterally adjacent to the second IC die.

In one or more thirteenth embodiments, further to the eleventh or twelfth embodiments, the second IC die is hybrid bonded to the first region of the top surface of the base die, and a second conformal layer is on a sidewall of the second IC die and over the second region of the top surface of the base die.

In one or more fourteenth embodiments, further to the eleventh through thirteenth embodiments, the second conformal layer is on a third inorganic dielectric material and one or more through dielectric vias (TDVs) embedded in the third inorganic dielectric material, wherein the third inorganic dielectric material and the one or more TDVs are laterally adjacent the base die.

In one or more fifteenth embodiments, further to the eleventh through fourteenth embodiments, the conformal layer comprises one or more of diamond, graphene, graphite, or a compound of boron and nitrogen.

In one or more sixteenth embodiments, further to the eleventh through fifteenth embodiments, the conformal layer comprises a metal.

In one or more seventeenth embodiments, further to the eleventh through sixteenth embodiments, the structural member is directly on the metal of the conformal layer or a second metal layer is in contact with the metal of the conformal layer and in contact with the structural member.

In one or more eighteenth embodiments, a system comprises multichip composite device according to any of the preceding embodiments, and one or more of a power supply coupled to the multichip composite device and/or a thermal solution coupled to the multichip composite device.

In one or more nineteenth embodiments, a system comprises a multichip composite device, comprising one or more integrated circuit (IC) dies over a top surface of a base die, a conformal layer on a top surface of an uppermost one of the one or more IC dies and on a sidewall surface extending between the top surface and a bottom surface of the uppermost one of the IC dies, an inorganic dielectric material on a portion of the conformal layer, the inorganic dielectric material over a second region of the top surface of the base die, and laterally adjacent the sidewall surface of the uppermost IC die, wherein the conformal layer comprises a greater thermal conductivity than the inorganic dielectric material, and a structural member over the conformal layer, a power supply coupled to the IC dies, and a heat exchanger over the structural member.

In one or more twentieth embodiments, further to the nineteenth embodiments, the one or more IC dies comprise the uppermost IC die hybrid bonded to a second one of the one or more IC dies, and wherein the conformal layer extends between the inorganic dielectric material and a second inorganic dielectric material laterally adjacent to the second IC die.

In one or more twenty-first embodiments, further to the nineteenth or twentieth embodiments, the second IC die is hybrid bonded to the first region of the top surface of the base die, and a second conformal layer is on a sidewall of the second IC die and over the second region of the top surface of the base die.

In one or more twenty-second embodiments, further to the nineteenth through twenty-first embodiments, the second conformal layer is on a third inorganic dielectric material and one or more through dielectric vias (TDVs) embedded in the third inorganic dielectric material, wherein the third inorganic dielectric material and the one or more TDVs are laterally adjacent the base die.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. A multichip composite device, comprising:
a first region of a bottom surface of an integrated circuit (IC) die hybrid bonded to a first region of a top surface of a base die, wherein a bottom surface of the base die, opposite the top surface of the base die, is to interconnect to a substrate;
a conformal layer on a top surface of the IC die, opposite the bottom surface of the IC die, and on a sidewall surface of the IC die, the sidewall surface extending between the top and bottom surfaces of the IC die;
an inorganic dielectric material on a portion the conformal layer, over a second region of the top surface of the base die, and laterally adjacent the sidewall surface of the IC die, wherein the conformal layer comprises a greater thermal conductivity than the inorganic dielectric material; and
a structural member coupled to the conformal layer.

2. The multichip composite device of claim 1, wherein the conformal layer is over the second region of the top surface of the base die and in contact with a metal pad coupled to the base die.

3. The multichip composite device of claim 1, wherein the conformal layer is on a second inorganic dielectric material and one or more through dielectric vias (TDVs) embedded in the second inorganic dielectric material, wherein the second inorganic dielectric material and the one or more TDVs are laterally adjacent the base die.

4. The multichip composite device of claim 1, wherein the conformal layer comprises a metal.

5. The multichip composite device of claim 1, wherein the metal comprises one or more of copper, aluminum, silver, or gold.

6. The multichip composite device of claim 1, wherein the conformal layer comprises one or more of diamond, graphene, graphite, or a compound of boron and nitrogen.

7. The multichip composite device of claim 1, wherein the structural member is directly on the conformal layer.

8. The multichip composite device of claim 1, wherein the conformal layer comprises a metal and a second metal layer is in contact with the conformal layer and in contact with the structural member.

9. The multichip composite device of claim 8, wherein the second metal layer is between the structural member and the inorganic dielectric material.

10. The multichip composite device of claim 8, wherein a second dielectric material laterally adjacent to the second metal layer is in contact with the inorganic dielectric material and in contact with the inorganic dielectric material.

11. A multichip composite device, comprising:
a base die comprising a bottom surface to interconnect to a substrate;
a stack of one or more integrated circuit (IC) dies over a first region of a top surface of the base die, opposite the bottom surface of the base die;
a conformal layer on a top surface of an uppermost one of the one or more IC dies and on a sidewall surface of the uppermost one of the IC dies;
an inorganic dielectric material on a portion of the conformal layer, the inorganic dielectric material over a second region of the top surface of the base die, and laterally adjacent the sidewall surface of the uppermost IC die, wherein the conformal layer comprises a greater thermal conductivity than the inorganic dielectric material; and
a structural member over the conformal layer.

12. The multichip composite device of claim 11, wherein the one or more IC dies comprise the uppermost IC die hybrid bonded to a second one of the one or more IC dies, and wherein the conformal layer extends between the inorganic dielectric material and a second inorganic dielectric material laterally adjacent to the second IC die.

13. The multichip composite device of claim 12, wherein the second IC die is hybrid bonded to the first region of the top surface of the base die, and a second conformal layer is on a sidewall of the second IC die and over the second region of the top surface of the base die.

14. The multichip composite device of claim 13, wherein the second conformal layer is on a third inorganic dielectric material and one or more through dielectric vias (TDVs) embedded in the third inorganic dielectric material, wherein the third inorganic dielectric material and the one or more TDVs are laterally adjacent the base die.

15. The multichip composite device of claim 11, wherein the conformal layer comprises one or more of diamond, graphene, graphite, or a compound of boron and nitrogen.

16. The multichip composite device of claim 11, wherein the conformal layer comprises a metal.

17. The multichip composite device of claim 16, wherein the structural member is directly on the metal of the conformal layer or a second metal layer is in contact with the metal of the conformal layer and in contact with the structural member.

18. A system comprising:
a multichip composite device, comprising:
one or more integrated circuit (IC) dies over a top surface of a base die;
a conformal layer on a top surface of an uppermost one of the one or more IC dies and on a sidewall surface extending between the top surface and a bottom surface of the uppermost one of the IC dies;
an inorganic dielectric material on a portion of the conformal layer, the inorganic dielectric material over a second region of the top surface of the base die, and laterally adjacent the sidewall surface of the uppermost IC die, wherein the conformal layer comprises a greater thermal conductivity than the inorganic dielectric material; and
a structural member over the conformal layer;
a power supply coupled to the IC dies; and
a heat exchanger over the structural member.

19. The system of claim 18, wherein the one or more IC dies comprise the uppermost IC die hybrid bonded to a second one of the one or more IC dies, and wherein the conformal layer extends between the inorganic dielectric material and a second inorganic dielectric material laterally adjacent to the second IC die.

20. The system of claim 19, wherein the second IC die is hybrid bonded to the first region of the top surface of the base die, and a second conformal layer is on a sidewall of the second IC die and over the second region of the top surface of the base die.

21. The system of claim 20, wherein the second conformal layer is on a third inorganic dielectric material and one or more through dielectric vias (TDVs) embedded in the third inorganic dielectric material, wherein the third inorganic dielectric material and the one or more TDVs are laterally adjacent the base die.
